(19) United States
(12) Patent Application Publication
(10) Pub. No.: US 2005/0064724 A1
(43) Pub. Date: Mar. 24, 2005

(54) Method and apparatus for forming low permittivity film and electronic device using the film

(76) Inventors: Takashi Sugino, Osaka (JP); Masaki Kusuhara, Tokyo (JP); Masaru Umeda, Tokyo (JP)

Correspondence Address: RANDALL J. KNUTH P.C., 4921 DESOTO DRIVE, FORT WAYNE, IN, 46815, US

(21) Appl. No.: 10/489,126

(22) PCT Filed: Sep. 10, 2002
(86) PCT No.: PCT/JP02/09227

(30) Foreign Application Priority Data
Sep. 10, 2001 (JP) 2001-274345

(51) Int. Cl. H01L 21/31; H01L 21/469

(52) U.S. Cl. 438/778; 438/783

(57) ABSTRACT

A film formation method enables the creation of a low dielectric constant boron-carbon-nitrogen thin film. The film formation method includes the steps of generating plasma in a film formation chamber, reacting boron and carbon with nitrogen atoms inside the film formation chamber, forming a boron-carbon-nitrogen film on a substrate, and thereafter subjecting the formed film to light exposure (e.g., ultraviolet and/or infrared).

### BACKGROUND OF THE INVENTION

1. Field of the Invention

The present invention relates to a film formation method for producing a film that includes boron, carbon, and nitrogen, and an electronic device that utilizes the same.

2. Description of the Related Art

Until now SiO₂ and SiN films formed by the plasma CVD (chemical vapor deposition) method have been used as wiring interlayer insulation thin films and protection films in semiconductor integrated circuits. However, with the increasing integration of transistors, the problem has arisen of wiring delays occurring due to the volume between wirings, which is a factor in inhibiting high speed electronic switching operations. Also, there is a demand for improving the wiring delay in liquid crystal display panels.

Lowering the dielectric constant of wiring interlayer insulation thin films is necessary in order to solve this problem, and a new material having a low dielectric constant is required for interlayer insulation films. Given this situation, although organic materials and porous materials have gained attention and make realization of an extremely low dielectric constant (dielectric constant of κ ˜2.5 or less) possible, chemically there are problems in terms of mechanical tolerance and thermal conductivity. Also, although extremely low dielectric constants of 2.2 have recently been achieved in boron nitride thin films, it is known that problems exist in terms of hygroscopic tolerance.

Although, in this type of situation, boron-carbon-nitrogen thin films are attracting attention, the status quo is that plasma CVD film formation technology has not been established and that even lower dielectric constants are desired. The present invention was arrived at in view of the above situation, and has as its object to provide a film formation method that can form a low dielectric constant boron-carbon-nitrogen thin film.

### SUMMARY OF THE INVENTION

The film formation method of the present invention for solving the above problems is characterized by having the processes of generating plasma in a film formation chamber, reacting boron and carbon with nitrogen atoms inside the film formation chamber, forming a boron-carbon-nitrogen film on a substrate, and thereafter subjecting the film to light exposure (e.g., using light within a particular wavelength range such as ultraviolet or infrared). Whether the light exposure process is performed in the film formation chamber or as one part of the manufacturing process after film formation, the same low dielectric constant effect can be attained.

Also, the film formation method of the present invention for achieving the above object is characterized by performing ultraviolet lighting (i.e., exposing the film to ultraviolet light/radiation) for several minutes using a mercury lamp after film formation. Optimum conditions can be attained by adjusting the lighting intensity and lighting time.

Further, as a light source, it is also possible to use a xenon lamp or a deuterium lamp.

Moreover, the film formation method of the present invention for achieving the above object, after forming the film, can include the performance of an infrared lighting step using an infrared lamp to thereby heat the thin film. Setting this holding temperature at 250° C. to 550° C. is preferred. 350° C. to 450° C. is more preferable, and 400° C. to 450° C. is even more preferable. At 250° C. or less, the low dielectric constant effect cannot be seen to any great extent, and at over 550° C. an increase in the dielectric constant occurs.

### BRIEF DESCRIPTION OF THE DRAWINGS

The above-mentioned and other features and advantages of this invention, and the manner of attaining them, will become more apparent and the invention will be better understood by reference to the following description of various embodiments of the invention taken in conjunction with the accompanying drawings, wherein:

FIG. 1 is a cross sectional drawing showing the film formation apparatus according to a first embodiment of the present invention;

FIG. 2 is a graph showing a comparison of dielectric constants both before and after performance of a lighting step, with respect to lighting time;

FIG. 3 is a graph showing a comparison of dielectric constants both before and after heat processing, with respect to heat processing temperature;

FIG. 4 is a cross sectional drawing showing the film formation apparatus according to a third embodiment of the present invention;

FIG. 5 is a cross sectional drawing showing the film formation apparatus according to a fourth embodiment of the present invention;

FIG. 6 is a schematic cross sectional drawing of an integrated circuit utilizing a boron carbon nitride film formed by a film formation method according to an embodiment of the present invention; and

FIG. 7 is a schematic cross sectional drawing of an integrated circuit utilizing a boron carbon nitride film formed by a film formation method according to an embodiment of the present invention.

Corresponding reference characters indicate corresponding parts throughout the several views. The exemplifications set out herein illustrate at least one preferred embodiment of the invention, in one form, and such exemplifications are not to be construed as limiting the scope of the invention in any manner.

### DETAILED DESCRIPTION OF THE INVENTION

Description of the Reference Numerals

1: Cylindrical container
2: Dielectric binding plasma generating section
3: Matching unit
4: High frequency power supply
5: Nitrogen gas introduction section
6: Substrate holding section
7: Heater
8, 9: Introduction sections
10: Exhaust section
50: Plasma
60: Substrate
61: Boron carbon nitride film
501: Transistor
502: Wiring
503: Interlayer insulation thin film
504: Protection film
   Preferred Embodiments of the Invention

Hereunder, the film formation method and film formation apparatus of the present invention will be explained in detail with reference to the drawings.

Embodiment 1

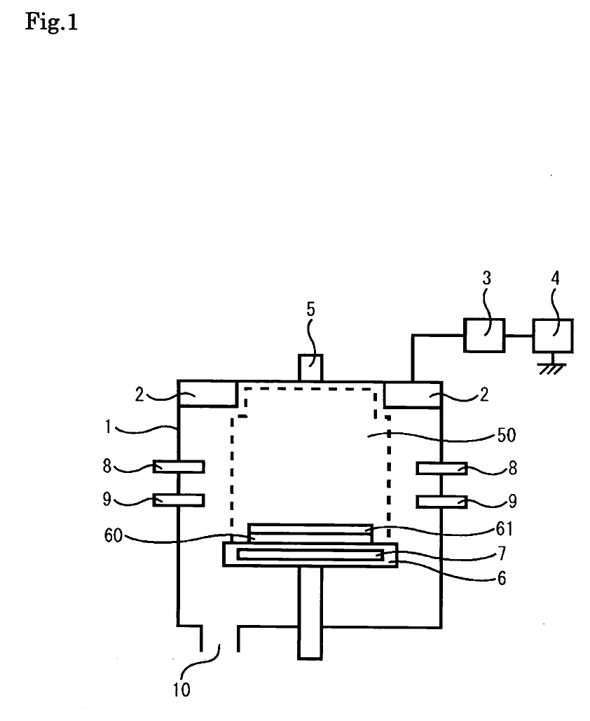

FIG. 1 is a schematic side view showing the film formation apparatus for implementing the film formation method of a first embodiment of the present invention. A dielectric binding plasma generating section 2 is provided in a cylindrical housing 1 and is connected to a high frequency power supply 4 via a matching unit 3.

The high frequency power supply 4 can supply high frequency power of up to 1 to 10 kw. Nitrogen gas is supplied from the nitrogen gas introduction section 5 to produce plasma 50. The substrate 60 is placed in the substrate holding section 6, and the heater 7 is installed in the substrate holding section 6. The temperature of the substrate 60 can be set within a range from room temperature to 600° C. by the heater 7. In the cylindrical container 1, the introduction section 8 for introducing boron chloride gas with hydrogen gas as a carrier is provided.

Also, an introduction section 9 for introducing a hydrocarbon gas into the cylindrical container 1 is provided. An exhaust section 10 is installed under the substrate holding section 6.

With respect to the supply flow range of each gas, the flow ratio of the nitrogen gas flow to the boron chloride flow (nitrogen gas/boron chloride) is 0.1 to 10.0, the flow ratio of the hydrocarbon gas flow to the boron chloride flow (hydrocarbon gas/boron chloride) is 0.01 to 5.0, and the flow ratio of the hydrogen gas flow to the boron chloride flow (hydrogen gas/boron chloride) is 0.05 to 5.0.

A p-type silicon substrate 60 is placed in the substrate holding section 6, the container 1 exhausted to 1×10⁻⁶ Torr, and the substrate temperature set to 300° C. Thereafter, nitrogen gas is introduced into the cylindrical container 1 from the introduction section 5. Plasma 50 is generated by supplying high frequency power (13.56 MHz) at 1 kw. Then, boron chloride is conveyed into the container 1 with hydrogen gas as a carrier, methane gas is supplied to the container 1, and the gas inside the container 1 is adjusted to 0.6 Torr, to synthesize a boron carbon nitride film 61.

The boron chloride and methane gas do not make the plasma, but the boron chloride and methane gas are separated by the nitrogen plasma, producing boron atoms and carbon atoms, and these react with the nitrogen atoms to produce the boron carbon nitride film 61. The chlorine combines with the hydrogen atoms to produce hydrogen chloride, inhibiting chlorine atom intake into the interior of the film. After film formation, lighting/exposure of the surface of the film is performed using a mercury lamp. It is illuminated for 4 minutes in a normal atmosphere at room temperature.

A 100 nm boron carbon nitride film 61 is deposited on the p-type silicon substrate 60, Au is vapor deposited on the boron carbon nitride film 61, and after an electrode is formed, the volume-to-voltage characteristic is measured, and the dielectric constant is evaluated using the volume value of the accumulation region of a metal/boron carbon nitride film/p-type silicon structure and the thickness of the boron carbon nitride film 61. In a film having a dielectric constant of 2.8 to 3.0 prior to lighting/exposure, a dielectric constant of a low value of 2.2 to 2.4 can be attained after 4 minutes of lighting.

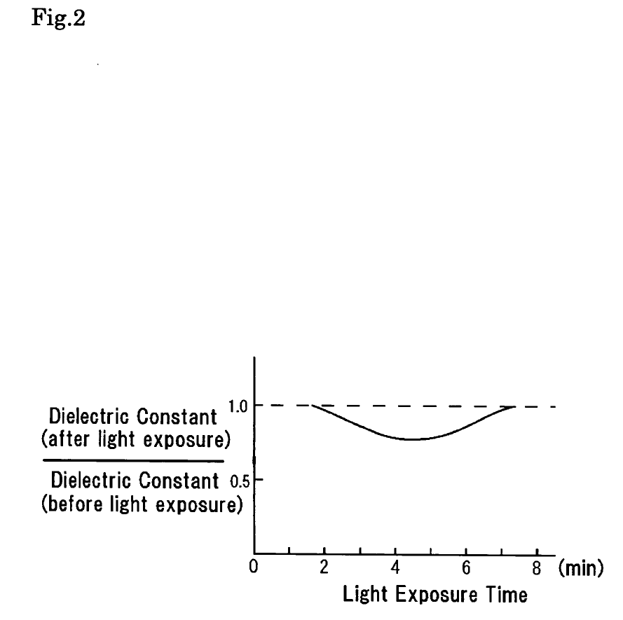

Also, an examination of the relationship between the ratio of the dielectric constant of the film before and after lighting to the lighting time is shown in FIG. 2. Where lighting is initiated using a mercury lamp (800 mmW/cm², distance to lens 15 cm, in normal atmosphere), a reduction of the dielectric constant can be recognized with a lighting time of from 3 to 6 minutes.

Although in the present embodiment nitrogen gas, boron chloride and methane gas were used as raw material gases, ammonia gas can also be used as the nitrogen material. Also, diborane gas can be used instead of boron chloride. Further, besides methane gas, an organic compound of boron and nitrogen such as a hydrocarbon gas like ethane gas, acetylene gas, or the like, or trimethylboron can be used. Moreover, although a mercury lamp was used as the light source for lighting/exposure, a xenon lamp or deuterium lamp can also be used.

Embodiment 2

The second embodiment of the present invention uses the same film formation apparatus as the first embodiment. A dielectric binding plasma generating section 2 is provided in a cylindrical housing 1 and is connected to a high frequency power supply 4 via a matching unit 3.

The high frequency power supply 4 can supply high frequency power of 1 to 10 kw. Nitrogen gas is supplied from the nitrogen gas introduction section 5 to produce plasma 50. The substrate 60 is placed in the substrate holding section 6, and the heater 7 is installed in the substrate holding section 6. The temperature of the substrate 60 can be set within a range from room temperature to 600° C. by the heater 7.

In the cylindrical container 1, the introduction section 8 for introducing boron chloride gas with hydrogen gas as a carrier is provided. Also, an introduction section 9 for introducing a hydrocarbon gas into the cylindrical container 1 is provided. An exhaust section 10 is installed under the substrate holding section 6.

With respect to the supply flow range of each gas, the flow ratio of the nitrogen gas flow to the boron chloride flow (nitrogen gas/boron chloride) is 0.1 to 10.0, the flow ratio of the hydrocarbon gas flow to the boron chloride flow (hydrocarbon gas/boron chloride) is 0.01 to 5.0, and the flow ratio of the hydrogen gas flow to the boron chloride flow (hydrogen gas/boron chloride) is 0.05 to 5.0.

A p-type silicon substrate 60 is placed in the substrate holding section 6, the container 1 exhausted to 1×10⁻⁶ Torr, and the substrate temperature set to 300° C. Thereafter, nitrogen gas is introduced into the cylindrical container 1 from the introduction section 5. Plasma 50 is generated by supplying high frequency power (13.56 MHz) at 1 kw. Then, boron chloride is conveyed into the container 1 with hydrogen gas as a carrier, methane gas is supplied to the container 1, and the gas inside the container 1 is adjusted to 0.6 Torr, to synthesize a boron carbon nitride film 61.

The boron chloride and methane gas do not make the plasma. Instead, the boron chloride and methane gas are separated by the nitrogen plasma, producing boron atoms and carbon atoms. These boron and carbon atoms then react with the nitrogen atoms to produce the boron carbon nitride film 61.

The chlorine combines with the hydrogen atoms to produce hydrogen chloride, inhibiting chlorine atom intake into the interior of the film. After film formation, the formed sample is heated by infrared lamp heating and maintained at 400° C. for 10 minutes.

A 100 nm boron carbon nitride film 61 is deposited on the p-type silicon substrate 60, Au is vapor deposited on the boron carbon nitride film 61, and after an electrode is formed, the volume-to-voltage characteristic is measured. The dielectric constant is evaluated using the volume value of the accumulation region of a metal/boron carbon nitride film/p-type silicon structure and the thickness of the boron carbon nitride film 61. In a film having a dielectric constant of 2.8 to 3.0 prior to heating, a dielectric constant of a low value of 2.2 to 2.4 can be achieved after heat treatment at a holding temperature of 400° C.

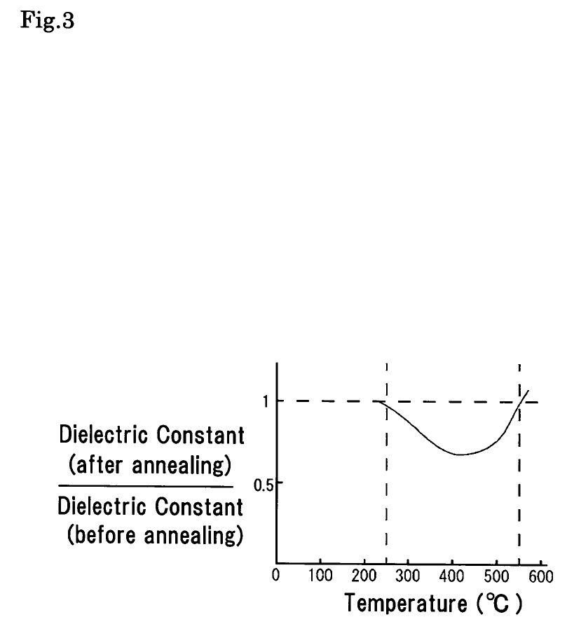

Also, an examination of the ratio of the dielectric constant of film subjected to heat treatment under various temperatures to the dielectric constant of a similarly produced film, evaluated without being heated, is shown in FIG. 3 as a function of heat treatment temperature. The holding temperature was 10 minutes. A reduction in dielectric constant was seen after heating at holding temperatures from 250° C. to 550° C.

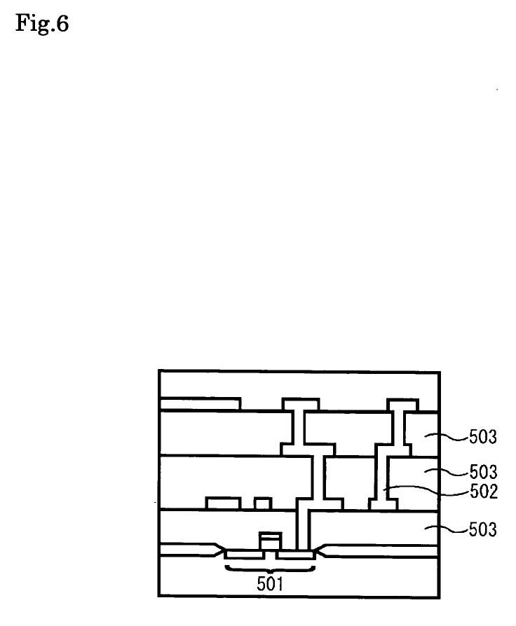

An example of an application of a boron carbon nitride film formed by the film formation method of the present invention will be explained using FIG. 6. In order to make wirings 502 into a multi-layer structure by increased integration of the transistor 501, it is necessary to use an interlayer insulation thin film 503 having a low dielectric constant between the wirings. Thus, the boron carbon nitride film formed by the present film formation method can be used for such an application.

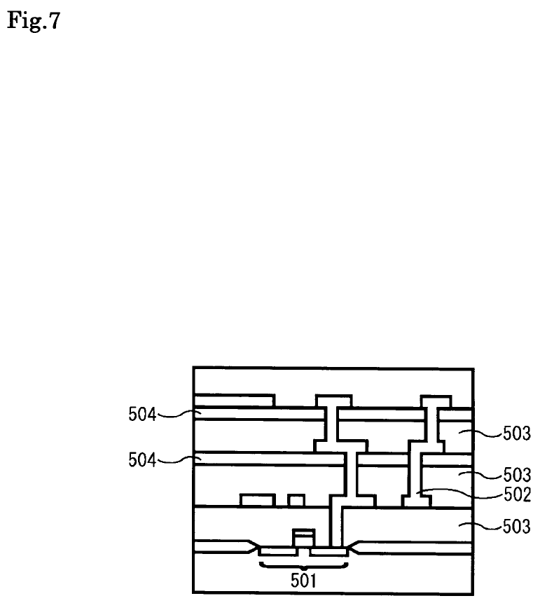

Also, where an organic thin film or porous film is used as the interlayer insulation thin film 503, although mechanical strength, hygroscopic property and the like are problems, the boron carbon nitride film formed by the film formation method of the present invention can be used as a protective film 504 of organic thin film or porous film as shown in FIG. 7. By incorporating combinations of these types of organic thin films, porous films and boron carbon nitride thin films, a dielectric constant lower than that of a boron carbon nitride thin film can be achieved, and an effective dielectric constant on the order of 1.9 can be attained.

Embodiment 3

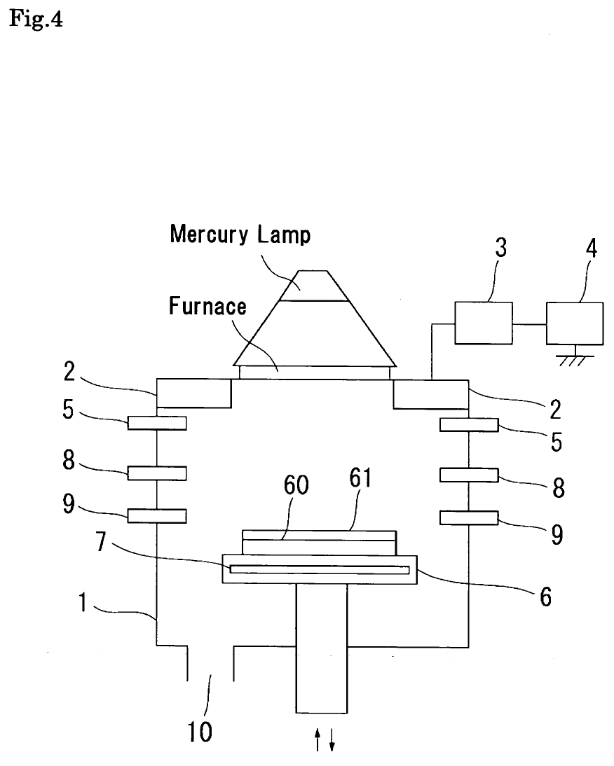

FIG. 4 is a schematic side view showing the film formation apparatus for implementing the film formation method of a third embodiment of the present invention. A dielectric binding plasma generating section 2 is provided in a cylindrical housing 1, and is connected to a high frequency power supply 4 via a matching unit 3.

The high frequency power supply 4 can supply high frequency power of up to 1 to 10 kw. Nitrogen gas is supplied from the nitrogen gas introduction section 5 to produce plasma 50. The substrate 60 is placed in the substrate holding section 6 and the heater 7 is installed in the substrate holding section 6. The temperature of the substrate 60 can be set within the range from room temperature to 600° C. by the heater 7.

Further, a window is provided in the top of the substrate holding section of the film formation chamber, so that the surface of the sample can be illuminated by a mercury lamp. When illuminated by the mercury lamp, the substrate holding section 6 can be moved toward the window. In the cylindrical container 1, the introduction section 8 for introducing boron chloride gas with hydrogen gas as a carrier is provided. Also, an introduction section 9 for introducing a hydrocarbon gas into the cylindrical container 1 is provided. An exhaust section 10 is installed under the substrate holding section 6.

With respect to the supply flow range of each gas, the flow ratio of the nitrogen gas flow to the boron chloride flow (nitrogen gas/boron chloride) is 0.1 to 10.0, the flow ratio of the hydrocarbon gas flow to the boron chloride flow (hydrocarbon gas/boron chloride) is 0.01 to 5.0, and the flow ratio of the hydrogen gas flow to the boron chloride flow (hydrogen gas/boron chloride) is 0.05 to 5.0.

A p-type silicon substrate 60 is placed in the substrate holding section 6, the container 1 exhausted to 1×10⁻⁶ Torr, and the substrate temperature set to 300° C. Thereafter, nitrogen gas is introduced into the cylindrical container 1 from the introduction section 5. Plasma 50 is generated by supplying high frequency power (13.56 MHz) at 1 kw. Then, boron chloride is conveyed into the container 1 with hydrogen gas as a carrier, methane gas is supplied to the container 1, and the gas inside the container 1 is adjusted to 0.6 Torr, to synthesize a boron carbon nitride film 61.

The boron chloride and methane gas do not make the plasma. Instead, the boron chloride and methane gas are separated by the nitrogen plasma, producing boron atoms and carbon atoms. These boron atoms and carbon atoms then react with the nitrogen atoms to synthesize the boron carbon nitride film 61.

The chlorine combines with the hydrogen atoms to produce hydrogen chloride, inhibiting chlorine atom intake into the interior of the film. After film formation, lighting/exposure of the substrate holding section 6 is performed for 3 to 6 minutes using a mercury lamp (800 mmW/cm2, distance to lens 15 cm, in normal atmosphere).

A 100 nm boron carbon nitride film 61 was deposited on the p-type silicon substrate 60, and Au was vapor deposited on the boron carbon nitride film 61. After an electrode was formed, the volume-to-voltage characteristic was measured. The dielectric constant was subsequently evaluated using the volume value of the accumulation region of a metal/boron carbon nitride film/p-type silicon structure and the thickness of the boron carbon nitride film 61, achieving a favorable value with a low dielectric constant.

Embodiment 4

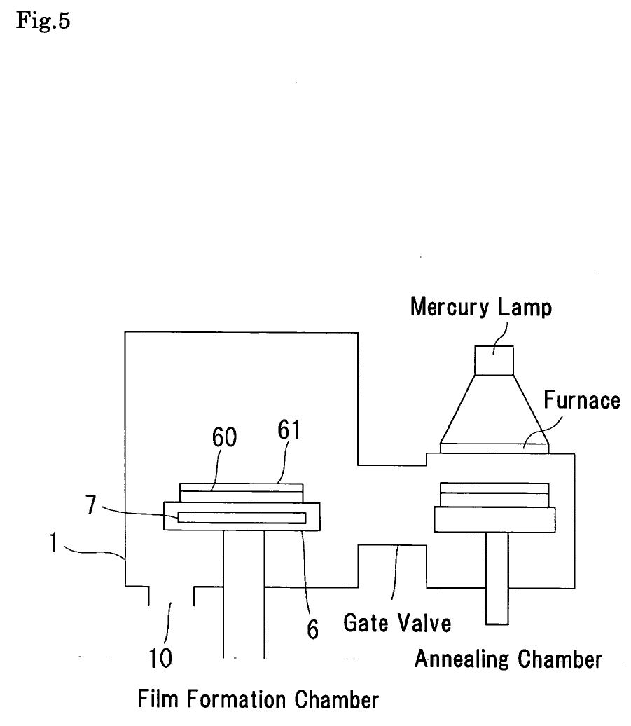

FIG. 5 is a schematic side view showing the film formation apparatus for implementing the film formation method of a fourth embodiment of the present invention. A dielectric binding plasma generating section 2 is provided in a cylindrical housing 1 and is connected to a high frequency power supply 4 via a matching unit 3. The high frequency power supply 4 can supply high frequency power of 1 to 10 kw.

Nitrogen gas is supplied from the nitrogen gas introduction section 5 to produce plasma 50. The substrate 60 is placed in the substrate holding section 6, and the heater 7 is installed in the substrate holding section 6. The temperature of the substrate 60 can be set within the range from room temperature to 600° C. by the heater 7. In the cylindrical container 1, the introduction section 8 for introducing boron chloride gas with hydrogen gas as a carrier is provided. Also, an introduction section 9 for introducing a type of hydrocarbon gas into the cylindrical container 1 is provided. An exhaust section 10 is installed under the substrate holding section 6. An annealing chamber is installed for maintaining heating of the film, via the film formation chamber and a gate valve, such that lighting/exposure of the film can be performed by a mercury lamp.

With respect to the supply flow range of each gas, the flow ratio of the nitrogen gas flow to the boron chloride flow (nitrogen gas/boron chloride) is 0.1 to 10.0, the flow ratio of the hydrocarbon gas flow to the boron chloride flow (hydrocarbon gas/boron chloride) is 0.01 to 5.0, and the flow ratio of the hydrogen gas flow to the boron chloride flow (hydrogen gas/boron chloride) is 0.05 to 5.0.

A p-type silicon substrate 60 is placed in the substrate holding section 6, the container 1 exhausted to 1×10⁻⁶ Torr, and the substrate temperature set to 300° C. Thereafter, nitrogen gas is introduced into the cylindrical container 1 from the introduction section 5. Plasma 50 is generated by supplying high frequency power (13.56 MHz) at 1 kw. Then, boron chloride is conveyed into the container 1 with hydrogen gas as a carrier, methane gas is supplied to the container 1, and the gas inside the container 1 is adjusted to 0.6 Torr, to synthesize a boron carbon nitride film 61.

The boron chloride and methane gas do not make the plasma. Instead, the boron chloride and methane gas are separated by the nitrogen plasma, producing boron atoms and carbon atoms. These boron atoms and carbon atoms react with the nitrogen atoms to produce the boron carbon nitride film 61.

The chlorine combines with the hydrogen atoms to produce hydrogen chloride, inhibiting chlorine atom intake into the interior of the film. After film formation, the substrate temperature was set to 400° C. by a heater 7 installed inside the substrate holding section 6 and maintained at such a temperature for 10 minutes.

When a 100 nm boron carbon nitride film 61 was deposited on the p-type silicon substrate 60, Au was vapor deposited on the boron carbon nitride film 61. After an electrode was formed, the volume-to-voltage characteristic was measured. The dielectric constant was then evaluated using the volume value of the accumulation region of a metal/boron carbon nitride film/p-type silicon structure and the thickness of the boron carbon nitride film 61, achieving a favorable value with a low dielectric constant.

### INDUSTRIAL APPLICATION

The film formation method of the present invention, by radiating light onto the boron carbon nitride film produced by plasma vapor deposition, can form a boron carbon nitride film that is mechanically and chemically stable, and has hygroscopic tolerance, high thermal conductivity and a low dielectric constant. The film formation apparatus for performing plasma vapor deposition provides a nitrogen gas introduction means in a cylindrical container, plasma generating means and substrate holding means thereunder. The apparatus further provides a means for introducing a hydrocarbon and an organic material as boron chloride and a carbon supply between the nitrogen introduction means and substrate holding means. The nitrogen plasma and boron react with carbon atoms to form a boron carbon nitride film on the substrate. Thereafter, by providing a lighting/exposure process for a film formation sample, the process of the invention can be used to form at high speed a boron carbon nitride film that has hygroscopic tolerance, high thermal conductivity, and a low dielectric constant.

The boron carbon nitride film according to the present invention can be used as a wiring interlayer insulation thin film or as a protective film for an integrated circuit.

By using this film as a protective film on the surface of a semiconductor between a source and gate or gate and drain in a field effect transistor (FET) or bipolar transistor produced by a compound semiconductor (GaAs type, InP type, GaN type, etc.) with the aim of high frequency operation, the amount of flotation can be reduced, and the frequency characteristic improved.

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

1. A film formation method for a low dielectric constant film characterized by having a process of emitting light after forming a film including boron, carbon, and nitrogen atoms.

2. A film formation method for a low dielectric constant film characterized by utilizing any one of a mercury lamp, xenon lamp, and deuterium lamp as a light source for emitting light.

3. A film formation method for a low dielectric constant film characterized by utilizing an infrared lamp a light source for emitting light.

4. A semiconductor device characterized by using a film formed by the method described in claim 1 as a wiring interlayer film.

5. A semiconductor device characterized by using a film formed by the method described in claim 1 as a protective film.

6. An information processing and communication system characterized by having the device described in any one of claims 4 and 5.

7. A semiconductor device characterized by using a film formed by the method described in any one of claims 1 to 3 as a semiconductor surface protective film between any one of a source and gate, and a gate and drain, in any one of a field effect transistor and a bipolar transistor produced by a compound semiconductor.
